(19) United States
(12) Patent Application Publication
(10) Pub. No.: US 2009/0172495 A1
(43) Pub. Date: Jul. 2, 2009

(54) Methods and Apparatuses for Parallel Decoding and Data Processing of Turbo Codes

(75) Inventors: Le Wang, Beijing (CN); Hongwen Yang, Beijing (CN); Hong Kui Yang, San Diego, CA (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: VIA TELECOM, INC., San Diego, CA (US)

(21) Appl. No.: 12/344,302

(22) Filed: Dec. 26, 2008

Related U.S. Application Data
(60) Provisional application No. 61/017,171, filed on Dec. 27, 2007.

(51) Int. Cl. H03M 13/05; G06F 11/10

(52) U.S. Cl. 714/755; 714/E11.032

(57) ABSTRACT

Methods and apparatuses for parallel decoding and data processing of Turbo codes are provided. The method includes: a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and a boundary moving step for moving at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size.

### BACKGROUND OF THE INVENTION

1. Field of the Invention

The invention relates to channel decoding in a wireless communication system, and more particularly to methods and apparatuses for parallel decoding of Turbo codes.

2. Description of the Related Art

A high performance and highly reliable coding scheme, a so-called Turbo code, that can be used in communication and data processing domains of a mobile communication system, a data recording system, a digital broadcasting system . . . etc. has recently been developed. However, with the ever-increasing demand for higher data rates, the Turbo code design is facing stringent challenges. Conventionally, the turbo codes are processed in serial for soft in soft out (SISO) algorithm in the component decoder. Such kind of process takes a large amount of clock cycles and thus, limits hardware decoding speed.

For clarity, the conventional serial decoding (SD) scheme for decoding the Turbo code is concisely illustrated in the following.

FIG. 1 is a diagram showing a conventional iterative Turbo decoder (please refer to: C. Berrou, A. Glavieux, and P. Thitimajshima, “Near Shannon limit error-correcting coding and decoding: Turbo-codes (I),” Proc. 1993 IEEE Int. Conf. Commun. (ICC'93), Geneva, Switzerland, May 1993, pages 1064-1070 in detail). The decoder includes two component decoders (1 and 2), an interleaver and a de-interleaver to decode in an iterative manner. During each iteration, the first component decoder delivers its calculated extrinsic information (Le₁) to the second component decoder after interleaving to serve as the a priori information (La₂). Then the second component decoder feedbacks its extrinsic information (Le₂) to the first component decoder after de-interleaving, working as a priori information (La₁). The x and x′ in FIG. 1 are received information bits and its interleaved version, respectively. The y₁ and y₂ are received redundant bits produced by the two component Recursive Systematic Convolutional (RSC) encoders (not shown), respectively.

The function of the component decoder is to calculate the LLRs (Logarithm of Likelihood Ratio) for the information bits. Such calculation generally employs the Maximum A Posteriori Probability (MAP) algorithm (please refer to: L. R. Bahl, J. Cocke, F. Jelinek and J. Raviv, “Optimal decoding of linear codes for minimizing symbol error rate”, IEEE Trans.Inform.Theory, Vol. IT-20, 284-287 pages, March 1974 in detail) where the LLR for the ith information bit can be expressed as

$${LLR}_{i} = log \frac{{\sum }_{1} {α}_{i - 1} ( s ) {β}_{i} ( s ) {γ}_{i} ( s , 1 )}{{\sum }_{0} {α}_{i - 1} ( s ) {β}_{i} ( s ) {γ}_{i} ( s , 0 )} \qquad ( 1 )$$

The whole process is shown in FIG. 2. Apparently, to calculate αᵢ(s), we should calculate αᵢ₋₁(s) first. Meanwhile, α_{N-1}(s) can not be calculated until all the past αᵢ(s) have been obtained, and the situation is similar to βᵢ(s). Thus, as well known in the art, in the conventional SISO algorithm, the processing of one branch in trellis depends on all the past calculation results of the past branches and the whole outputs of the component decoding cannot be obtained until all the branches are processed. Thus, the processing of one iteration for one component decoder cannot be finished within N clock cycles (some extra clock cycles may be required to execute some other operations). Therefore, processing of one component of the SISO decoder requires at least N clock circles where N is the length of the trellis diagram (frame length of the Turbo code or the inter-leaver length). If the clock frequency is f_{c}, then the delay for processing of the MAP is more than

$${T}_{map} = \frac{N}{{f}_{c}} .$$

Suppose that the maximum iteration is Iₘₐₓ, then the delay for decoding one codeword of the Turbo code is more than

$${T}_{dec} = 2 {T}_{map} {I}_{max} = \frac{2 N}{{f}_{c}} {I}_{max} ,$$

which causes an information throughput of less than

$$R = \frac{N}{{T}_{dec}} = \frac{{f}_{c}}{2 {I}_{max}} .$$

For example, when f_{c}=100 MHz and Iₘₐₓ=8, the throughput cannot be larger than 6.25 Mbps. Note that with some early-stop iteration strategies, the actual number of iterations to successfully decode one codeword may be much less than Iₘₐₓ, but hardware must be designed to fulfill Iₘₐₓ.

To reduce the decoding delay and improve throughput, a parallel Turbo code decoding method has been proposed.

The general steps include dividing the whole codeword into Q sub-blocks and then decoding the Q sub-blocks with Q MAP processors in parallel. Thus, the required clock cycles are reduced to N/Q, and the decoding speed can be increased by a factor of Q. Unfortunately, problems exist due to the loss of the initial condition at the sub-block boundary, wherein when the codeword is not divided into sub-blocks, the computation in the boundary needs to obtain the past calculation result.

Random or arbitrary initialization for each sub-block will lead to a performance loss that is unacceptable. So directly working in parallel causes a problem of how to initialize the forward and backward variables at the boundary of each segment.

In order to obtain a better initial condition in the sub-block boundaries, two parallel decoding schemes for Turbo codes have been proposed. One is proposed by Jah-Ming Hsu and Chin-Liang Wang, “a parallel decoding scheme for turbo codes” in Proc.ISCAS'98, Vol. 4, June 1998, pages 445-448 (hereinafter called OL method in brevity).

FIG. 3 shows is a diagram illustrating overlapped sub-blocks for computation of αᵢ(s) for a conventional OL method. For specific sub-blocks from number k to (k+M−1) with length M, the calculation can be started from (k-L). To obtain all of the forward variables αᵢ(s) in one component decoder within one iteration, the whole processing of the codeword with Q segments and L overlappings requires

$$\frac{N}{Q} + L$$

clock cycles instead of

$$\frac{N}{Q}$$

cycles, and the decoding speed will be slowed down by a factor of

$$\frac{N}{N + LQ} .$$

The larger the L and Q are, the slower the decoding speed will be. For instance, assuming that the block length is 2298, if we segment it into Q=50 sub-blocks and the overlap length is L=30, then

$$\frac{2298}{50} + 30 \approx 76$$

clock cycles are required to produce all the forward variables, instead of

$$\frac{2298}{50} \approx 46$$

cycles. Hence, the MAP decoding speed can only be improved by 30 times, which is far less than Q=50, which what it originally was.

Another parallel decoding scheme for Turbo codes has been proposed by Seokhyn Yoon and Yeheskel Nar-Ness: “A parallel MAP algorithm for low latency turbo decoding”, IEEE communications letters, VOL. 6, NO. 7, July 2002 (hereinafter called the SBI method). It utilizes storing the boundary value calculated in a pervious iteration, and uses the calculated boundary value as an approximated initial condition for calculating the sub-block boundary in a next iteration.

Compared with the overlapping method, such method requires no redundant computations. Hence, the decoding speed can increase linearly with the number of segments Q. However, the method requires an extra memory of size 2×Q×₂^{m}v to store the final results of αₖ₋₁^{(p)}(s) in a previous iteration, where v is the number of bits used to quantize the variables, and 2^{m} is the number of states in trellis.

In summary, the drawback of the OL method is that due to overlapping requirements, some extra computation time delay occurs, which decreases the decoding speed, especially when Q is large and N is small. As to the SBI method, some extra memory is required to store the intermediate boundary information. Thus, when Q is large, the portion of storage can not be ignored.

### BRIEF SUMMARY OF THE INVENTION

In the invention, methods and apparatuses for parallel decoding and data processing of Turbo codes are provided. The previously described drawbacks of decoding speed and decoding accuracy in the conventional design are overcome without largely increasing the memory size.

According to an embodiment of the invention, a method for parallel decoding and data processing of Turbo codes comprises: a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and a boundary moving step for moving at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size.

According to another embodiment of the invention, a method for parallel decoding and data processing of Turbo codes comprises: a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and a storing step for storing an index of a state (s*) of a maximum probability of the calculation results for a forward processing or a backward processing procedure of a pth decoding iteration for the qth sub-block during the pth decoding iteration, wherein when an initial condition (s) is with the state of the maximum probability in the forward processing or backward processing procedure of a (p+1)th decoding iteration for the qth sub-block, a reliability of the initial condition (s) is 0, and a start point of the forward or the backward processing of the qth sub-block is k, where 1≦q≦Q, and q′ is an integer, and p is a positive integer and 1≦p<P.

According to another embodiment of the invention, a method for parallel decoding and data processing of Turbo codes comprises: a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and a storing step for storing an index of a state (s*) of a maximum probability of the calculation results for a forward processing or a backward processing procedure of a pth decoding iteration for the qth sub-block during the pth decoding iteration, wherein when an initial condition (s) in a forward processing or a backward processing procedure of a (p+1)th decoding iteration for the qth sub-block is not compliant with the state of the maximum probability (s*), that is s≠s*, the initial condition relates to a difference between a reliability of the state (s*) of the maximum probability and a reliability of a state (s′) of a second highest probability.

According to another embodiment of the invention, an apparatus for parallel decoding and data processing of Turbo codes is provided, comprising a codeword dividing device and a boundary moving device. The codeword dividing device divides a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1. The boundary moving device moves at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size.

According to another embodiment of the invention, an apparatus for parallel decoding and data processing of Turbo codes is provided, comprising a parallel decoding and data processing device, a Turbo code decoding device and a storing device coupled to the parallel and data processing device. The parallel decoding and data processing device receives input data and comprises a codeword dividing device and a boundary moving device. The codeword dividing device divides a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1. The boundary moving device moves at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size. The Turbo code decoding device is coupled to the parallel decoding and data processing device and receives decoded data of the sub-blocks, wherein the Turbo code decoding device comprises a plurality of interleavers and a plurality of de-interleavers to Turbo decode the decoded data of the sub-blocks generated by the parallel decoding and data processing device. The storing device is coupled to the parallel decoding and data processing device and the Turbo code decoding device for storing the input data and decoded results.

Without overlapping sub-blocks and extra memory, better decoding results can still be obtained. Further, with overlapping sub-blocks, shorter overlap length is realized and fewer memory is required when the memory is used to store the initial conditions.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a diagram showing a conventional iterative Turbo decoder;

FIG. 2 is a flowchart shows the operation of a MAP algorithm;

FIG. 3 shows is a diagram illustrating overlapped sub-blocks for computation of αᵢ(s) in a conventional OL method;

FIG. 4A is a diagram illustrating an apparatus performing parallel decoding of Turbo codes according to a first embodiment of the invention;

FIG. 4B is a diagram illustrating a flow chart of a parallel Turbo code decoding method according to a first embodiment of the invention;

FIG. 5A is a diagram illustrating an apparatus performing parallel decoding of Turbo codes according to a second embodiment of the invention;

FIG. 5B is a diagram illustrating a flow chart of a parallel Turbo code decoding method according to a second embodiment of the invention;

FIG. 6A is a diagram illustrating an apparatus performing parallel decoding of Turbo codes according to a third embodiment of the invention;

FIG. 6B is a diagram illustrating a flow chart of a parallel Turbo code decoding method according to a third embodiment of the invention;

FIG. 7 is a diagram illustrating a sub-block in a parallel Turbo code decoding apparatus according to a third embodiment of the invention;

FIG. 8 is a diagram illustrating calculation of boundary positions of the forward and backward variable αᵢ(s) and βᵢ(s) according to an embodiment of the invention;

FIG. 9 is a diagram illustrating the process in two successive iterations for processing the sub-block boundary position according to an embodiment of the invention; and

FIGS. 10-17 are diagrams of simulated results of the present invention.

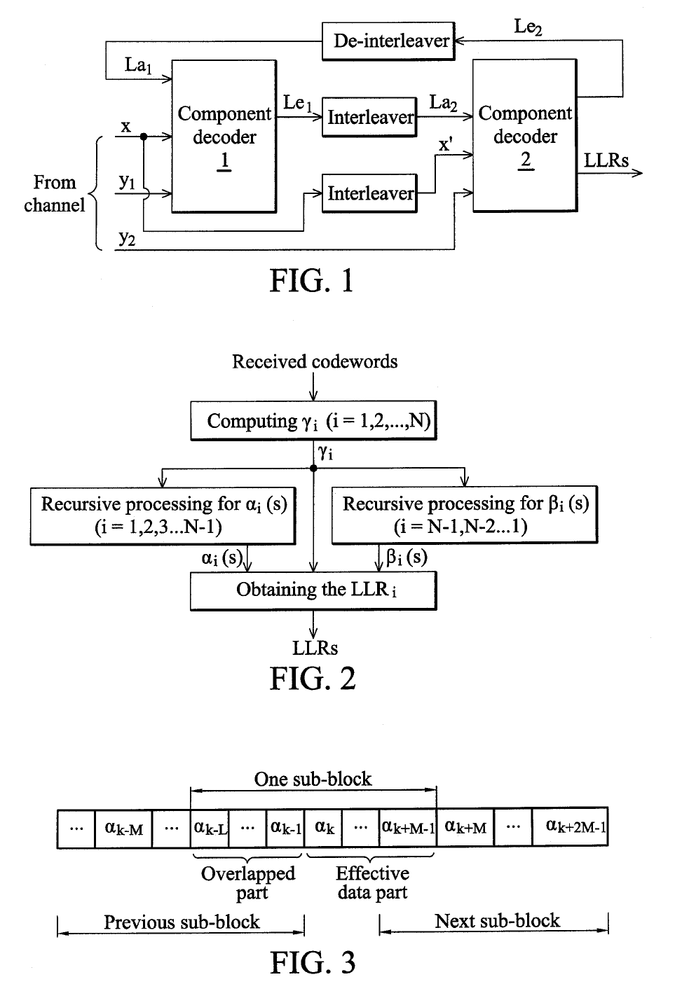

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

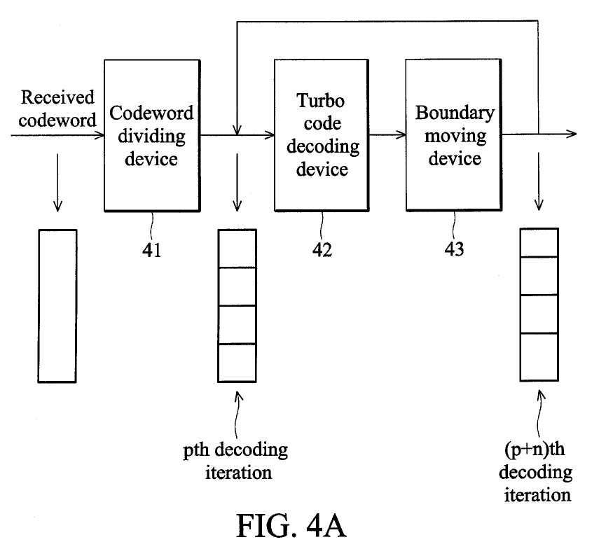

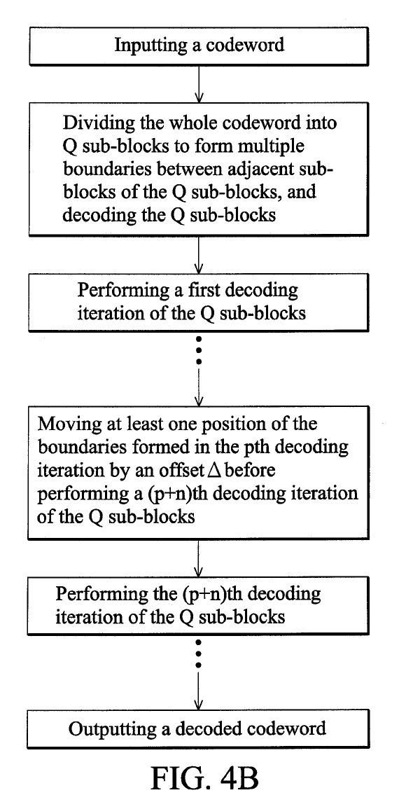

FIG. 4A and FIG. 4B are diagrams illustrating an apparatus performing parallel decoding of Turbo codes and a flow chart of the parallel Turbo code decoding method according to a first embodiment of the invention.

As shown in FIG. 4A, the parallel Turbo code decoding apparatus comprises a codeword dividing device 41, a Turbo code decoding device 42, and a boundary moving device 43. The codeword dividing device 41 divides the input codeword into Q non-overlapped sub-blocks, where the boundaries are formed between the Q sub-blocks (Q is a positive integer and Q>1). The Turbo code decoding device 42 comprises Q component decoders (not shown) to decode the Q sub-blocks in parallel. The Q sub-blocks are decoded by a maximum Iₘₐₓ times of iterations in the Turbo code decoding device 42. Suppose P times of iterations (where P is a positive integer and P>1), when the parallel Turbo code decoding apparatus is processing the pth iteration (where p is a positive integer and 1≦p<P), the sub-block boundaries after the codeword being divided would be shown as FIG. 4A. Before processing the (p+n)th decoding iteration (where n is a positive integer and 1≦n<(P−p)), the boundary moving device 43 moves at least one of the multiple sub-block boundaries that are divided in the pth iteration. However, it is preferred to move all of the sub-block boundaries divided in the pth iteration (for example, the divided sub-block boundaries divided in the (p+n)th iteration shown in FIG. 4A). Then, the parallel Turbo code decoding apparatus continues the rest of iteration processes. FIG. 4B is a diagram illustrating a flow chart of a parallel Turbo code decoding method according to a first embodiment of the invention. The scheme of moving a boundary is hereinafter called an MB scheme for brevity.

For the conventional parallel Turbo code decoding apparatus, performance degrades due to imprecise initial conditions at the start point of sub-block decoding. If the initial conditions of the sub-block boundary are set randomly or arbitrarily, imprecise soft output always occurs at the same boundary position, because the positions of the divided sub-block boundaries are unchanged during each iteration of the decoding process. According to the first embodiment of the invention, after one or more times of iterations of the decoding process, the boundary moving device 43 moves one or more sub-block boundaries with regard to the divided sub-block boundary in a previous iteration. In this manner, imprecise soft output due to imprecise initial conditions at the start point of sub-block decoding are distributed at different positions. Thus, imprecise factors are not accumulated, and the final decoding performance is further improved.

As one of ordinary skill in the art will readily appreciate, under the teaching of the first embodiment of the invention, that if it is set to begin at the first iteration, better decoding performance is achieved when the position of a sub-block boundary (for example, n=1) is moved and/or all positions of the sub-block boundaries are moved before each iteration. Additionally, one of ordinary skill in the art will also readily appreciate that by setting the amount of movement offset Δ for moving one or more boundary positions in each time to a fixed step size, hardware or software configuration may be accomplished much easier.

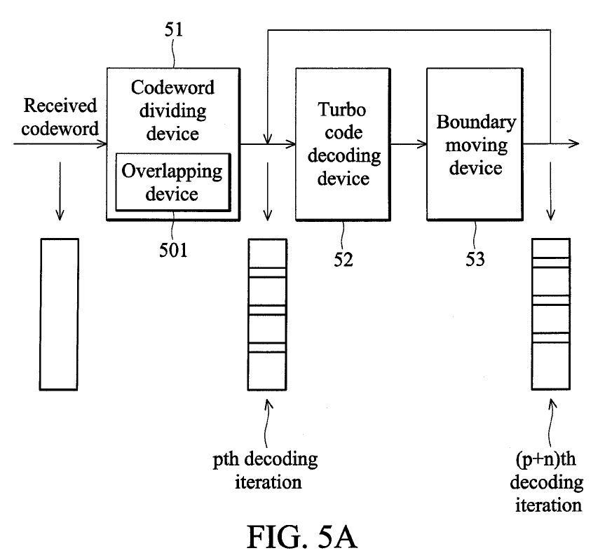

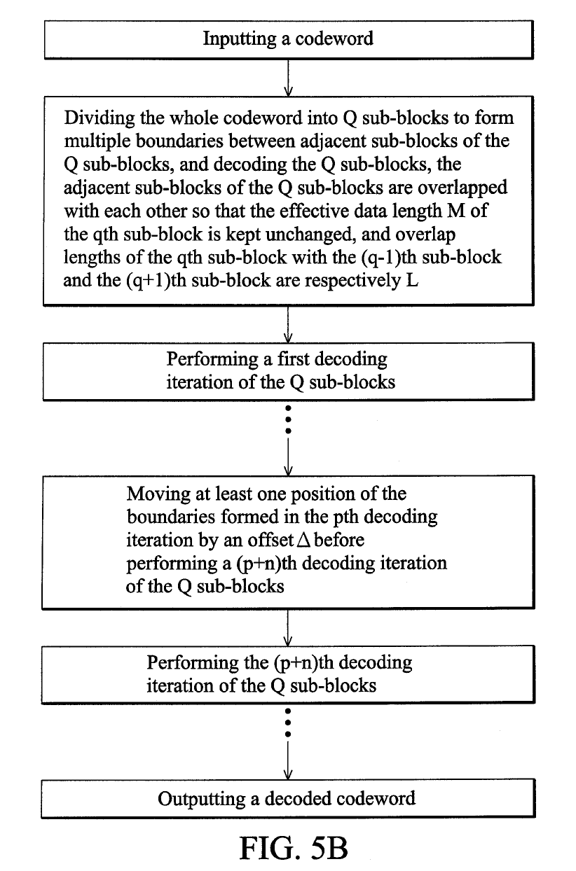

FIG. 5A and FIG. 5B are diagrams illustrating an apparatus performing parallel decoding of Turbo codes and the flow chart of the parallel Turbo code decoding method according to a second embodiment of the invention.

As shown in FIG. 5A, the parallel Turbo code decoding apparatus comprises a codeword dividing device 51 comprising an overlapping device 501, a Turbo code decoding device 52 and a boundary moving device 53. The codeword dividing device 51 divides the input codeword into Q overlapped sub-blocks via the overlapping device 501 therein (Q is a positive integer and Q>1), where the effective data length M is kept unchanged, and an overlap length of a medium sub-block (for example, the qth sub-block, 2≦q≦(Q−1), a previous sub-block (for example, the (q−1)th sub-block) and a next sub-block (for example, the (q+1)th sub-block) is L (L≧0). The Turbo code decoding device 52 comprises Q component decoders (not shown) to decode the Q sub-blocks in parallel. The Q sub-blocks are decoded by a maximum Iₘₐₓ times of iterations in the Turbo code decoding device 52. Suppose P times of iterations (where P is a positive integer and P>1), when the parallel Turbo code decoding apparatus is processing the pth iteration (where p is a positive integer and 1≦p<P), the sub-block boundary after the codeword being divided would be shown as FIG. 5A. Before processing the (p+n)th decoding iteration (where n is a positive integer and 1≦n<(P−p)), the boundary moving device 53 moves at least one of the multiple sub-block boundaries divided in the pth iteration. However, it is preferred to move all of the sub-block boundaries that are divided in the pth iteration (for example, the divided sub-block boundary that are divided in the pth iteration are shown as FIG. 5A). Then, the parallel Turbo code decoding apparatus continues the rest of iteration process. FIG. 5B is a diagram illustrating a flow chart of a parallel Turbo code decoding method according to a second embodiment of the invention.

FIG. 8 is a diagram illustrating sub-block boundary positions of the forward variable αᵢ(s) and the backward variable βᵢ(s) calculated in one iteration process in the conventional schemes, whether it is an OL or SBI scheme. FIG. 9 is a diagram illustrating the variation of the sub-block boundary between two iteration processes according to the second embodiment of the invention.

The α_{q}^{p} and β_{q+1}^{p} are the boundary positions of the qth sub-block during the pth iteration (the start points of the forward computation and backward computation). To be specific, assume that the start point of the forward variable αᵢ(s) is α_{q}^{p}, and the start point of the forward variable αᵢ(s) of the first sub-block is 1, and the start point of the forward variable αᵢ(s) of the Qth sub-block is α_{Q}^{p}. Similarly, assume that the start point for computing the backward variable βᵢ(s) of the qth sub-block is b_{q+1}^{p}, and the start point of the backward variable βᵢ(s) of the first sub-block is b₂^{p}, and the start point of the backward variable βᵢ(s) of the Qth sub-block is N. Before the first decoding iteration, for processing α, the first sub-block would be shorter, and the rest of the sub-blocks would be with equal length. Meanwhile, for processing β, it would be the opposite. Further, since α and β would be processed independently, the boundaries may be different. However, the start points would be unchanged in the conventional OL or SBI schemes.

Refer to FIG. 9, according to an embodiment of the invention, the overlap length between the sub-blocks is L, the effective data length of the sub-block is M, and the boundary of each sub-block formed during the first iteration is expected to be moved by the offset Δ during the second iteration. Thus, during the first iteration, a_{q}¹=(q−1)M+(q−2)L+1, and b_{q+1}¹=q(M+L), 2≦q≦Q−1 and during the second iteration, a_{q}²=(q−1)M+(q−2)L+1−Δ and b_{q+1}²=q(M+L)−Δ, 2≦q≦Q−1. According to an alternative embodiment of the invention, during the first iteration, a_{q}¹=(q−1)M−L+1, 2≦q≦Q−1, and during the second iteration, a_{q}²=(q−1)M−L+1−Δ, 2≦q≦Q−1. It should be understand that FIG. 9 only shows an exemplary diagram. According to an embodiment of the invention, the sub-block boundary may be moved in successive iterations, or may be moved in non-successive iterations; that is, in any intervals with any number of iterations spaced therebetween. When moving the sub-block boundary, it may be only to move one or few sub-block boundaries, or to move all sub-block boundaries. Further, when moving the sub-block boundary, variable offset may be used, i.e. Δ may be variable. However, fixed offset may also be used, i.e. Δ may be fixed. If a fixed offset Δ is used to move the sub-block boundaries during each iteration, after the first iteration, then a_{q}^{p}=(q−1)M+(q−2)L+1−Δ(p−1) and b_{q+1}^{p}=q(M+L)−Δ(p−1), 2≦q≦Q−1. According to an alternative embodiment of the invention, a_{q}^{p}=(q−1)M−L+1−Δ(p−1), 2≦q≦Q−1. It is noted that the start point described herein is merely an example. When practiced, since the length of the codeword, and the values of L and M may be different, the operation of the start point may also be different. One of ordinary skill in the art will also readily appreciate, with the illustration of the specification, various alterations and modifications of the operations may also be made for calculating the start point. As long as the positions of the boundaries are adequately moved to a different iteration of the decoding process, the spirit of the invention may still be realized.

For the conventional parallel Turbo code decoding apparatus, performance degrades due to imprecise initial conditions at the start point of sub-block decoding. For the conventional OL method for parallel Turbo code decoding, the initial conditions of the initial position of the overlapped sub-blocks are set randomly or arbitrarily. Even the approximated initial conditions of the sub-block are obtained by calculating over the L overlap length, before decoding the effective data portion of the sub-block, since the positions of the divided sub-block boundaries are unchanged in each iteration of the decoding process. Thus, the imprecise soft output still always occurs at the same boundary position. In order to remove the deviation accumulated in each iteration that causes the degradation of the performance, the conventional OL method requires longer overlap length L. According to the second embodiment of the invention, the approximated initial conditions of the start point of the effective data portion of the sub-block are obtained by calculating the variables of the overlapping portion of the sub-block in advance. After one or more iterations of decoding, the boundary moving device 53 moves one or more sub-block boundaries with regard to the divided sub-block boundary in a previous iteration. In this manner, the imprecise soft output due to the imprecise initial conditions at the start point of sub-block decoding are distributed at different positions. Thus, the imprecise factors are not accumulated, and the final decoding performance is further improved.

As one of ordinary skill in the art will readily appreciate, under the teaching of the second embodiment of the invention, that if it is set to begin at the first iteration, better decoding performance is achieved when the position of a sub-block boundary (for example, n=1) is moved and/or all positions of the sub-block boundaries are moved before each iteration. One of ordinary skill in the art will also readily appreciate that by setting the amount of movement offset Δ for moving one or more boundary positions in each time to a fixed step size, hardware or software configuration may be accomplished much easier.

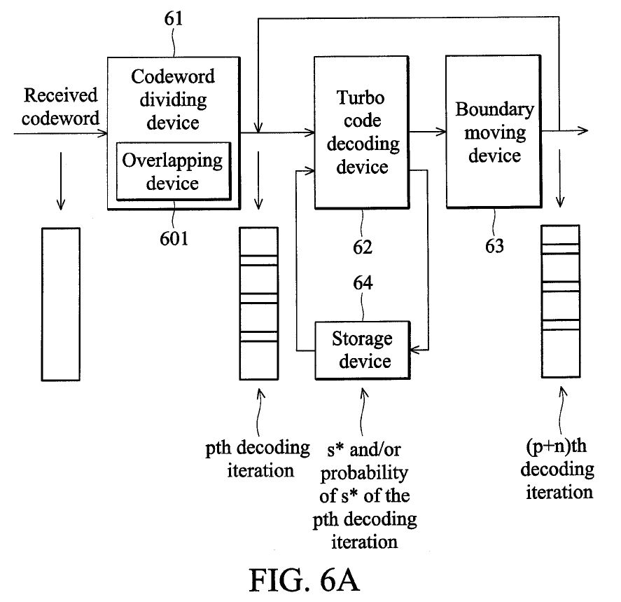

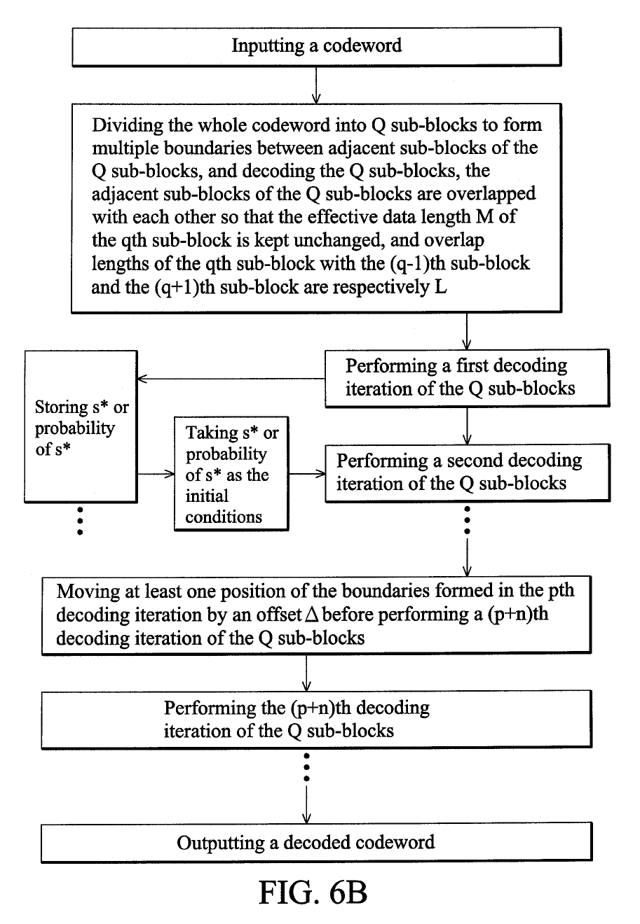

FIG. 6A and FIG. 6B are diagrams illustrating an apparatus performing parallel decoding of Turbo codes and the flow chart of the parallel Turbo code decoding method according to a third embodiment of the invention.

As shown in FIG. 6A, the parallel Turbo code decoding apparatus comprises a codeword dividing device 61 comprising an overlapping device 601, a Turbo code decoding device 62, a boundary moving device 63 and a storage device 64. The codeword dividing device 61 divides the input codeword into Q overlapped sub-blocks via the overlapping device 601 therein (Q is a positive integer and Q>1), where the effective data length M of the sub-block is kept unchanged, and an overlap length of a medium sub-block (for example, the qth sub-block, 2≦q≦(Q−1), a previous sub-block (for example, the (q−1)th sub-block) and a next sub-block (for example, the (q+1)th sub-block) is L (L≧0). The Turbo code decoding device 62 comprises Q component decoders (not shown) to decode the Q sub-blocks in parallel. The Q sub-blocks are decoded by a maximum Iₘₐₓ times of iterations in the Turbo code decoding device 62. Suppose P times of iteration (where P is a positive integer and P>1), when the parallel Turbo code decoding apparatus is processing the pth iteration (where p is a positive integer and 1≦p<P), the sub-block boundary after the codeword being divided would be shown as FIG. 6A. Before processing the (p+n)th decoding iteration (where n is a positive integer and 1≦n<(P−p)), the boundary moving device 63 moves at least one of the multiple sub-block boundaries divided in the pth iteration. However, it is preferred that all of the sub-block boundaries divided in the pth iteration (for example, the divided sub-block boundary that are divided in the pth iteration are shown as FIG. 6A) are moved. Then, the parallel Turbo code decoding apparatus continues the remaining iteration process.

In addition, during each iteration, a store index (hereinafter called SI) scheme may be employed to improve the previously described SBI method so as to store the boundary information by using fewer numbers of bits. The SI scheme may be employed in any parallel Turbo codes decoding process, for example, the conventional direct parallel decoding method, the OL parallel decoding method, or the parallel decoding method as previously described according to the first or second embodiments of the invention, to further reduce the required memory size for storing the boundary information.

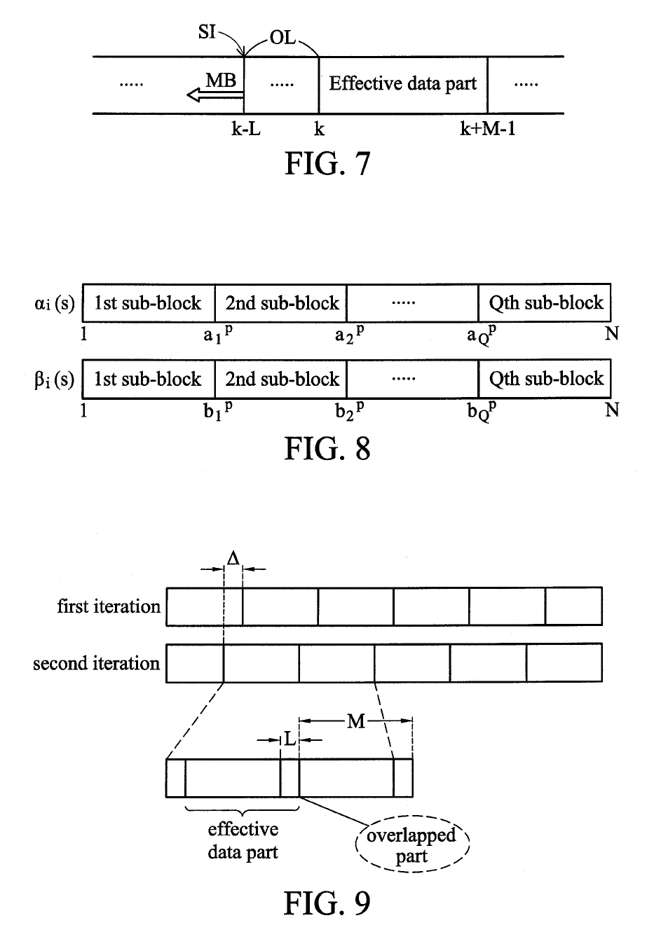

FIG. 7 is a diagram illustrating a sub-block, of the OL+SI scheme by using the OL scheme (it is also preferable to employ only SI scheme without the OL scheme), in parallel Turbo code decoding apparatus according to a third embodiment. It is noted that although an exemplary calculation of the forward variable αᵢ^{(s)} of a sub-block is illustrated here, however, it is also applicable for calculating the backward variable βᵢ^{(s)} and the invention should not be limited thereto. As shown in FIG. 7, the effective data portion starts from position k to (k+M−1), where the portion from position (k−L) to (k−1) is overlapped with the previous sub-block.

During the (p+1)th iteration, the calculation starts from position (k−L), and the initial condition employs:

log(α_{k-L}^{(p+1)}(s))=0 s=s*,

where

$${s}^{*} = arg max \{ {log}_{s} ( {α}_{k - L}^{( p )} ( s ) ) \}$$

is a state of a maximum probability of the calculation result (or hereinafter called the most possible state) obtained in a previous iteration (for example, in the pth iteration); that is, the state of the maximum probability. In this way, according to the third embodiment of the invention, the storage device 64 may only store a corresponding index of the most possible state s*, which requires only m bits of memory, instead of the 2^{m}v bits as the SBI scheme, where m is the number of bits required for storing a state and v is the number of bits used to quantize the variables.

Or, during the (p+1)th iteration, the calculation starts from position (k−L), and the initial condition employs:

$$log ( {α}_{k - L}^{( p )} ( s ) ) = \{ \begin{matrix} 0 , & s = {s}^{*} \\ log {α}_{k - L}^{( p )} ( {s}^{′} ) - log {α}_{k - L}^{( p )} ( {s}^{*} ) , & others\end{matrix} \} ,$$

where

$${s}^{*} = arg max \{ {log}_{s} ( {α}_{k - L}^{( p )} ( s ) ) \} and {s}^{′} = arg max \{ {log}_{s \neq {s}^{*}} ( {α}_{k - L}^{( p )} ( s ) ) \}$$

are first and second most possible states of the calculation results in the previous iteration (for example, the pth iteration), respectively; that is, the most possible state (a state of the highest probability) and the secondary most possible state (a state of a second highest probability). Thus, according to the third embodiment of the invention, the storage device 64 may only store corresponding index of the most possible state s* and the log α_{k-F}^{(p)}(s′)−log α_{k-L}^{(p)}(s*) indicating the possible reliability (or probability) of s*, which requires only m−v bits of memory, instead of the 2^{m}v bits as the SBI scheme, where m is the number of bits required for storing a state and v is the number of bits used to quantize the variables.

FIG. 6B is a diagram illustrating a flow chart of a parallel Turbo code decoding method according to the third embodiment of the invention.

Through the third embodiment of the invention, a further approximated initial condition of the start point of the effective data portion of the sub-block may be obtained by calculating the variables in the overlapping portion of the sub-block from the start point of the overlapping portion of the sub-block using the initial conditions obtained in a previous iteration stored in the storage device 64. After one or more iterations of decoding, the boundary moving device 63 moves one or more sub-block boundaries with regard to the divided sub-block boundary in a previous iteration. In this manner, imprecise soft output due to imprecise initial conditions at the start point of sub-block decoding are distributed at different positions. Thus, imprecise factors are not accumulated, and final decoding performance is further improved.

As one of ordinary skill in the art will readily appreciate, under the teaching of the third embodiment of the invention, that if it is set to begin at the first iteration, better decoding performance is achieved when the position of a sub-block boundary (for example, n=1) is moved and/or all positions of the sub-block boundaries are moved before each iteration. One of ordinary skill in the art will also readily appreciate that by setting the amount of movement offset Δ for moving one or more boundary positions in each time to a fixed step size, hardware or software configuration may be accomplished much easier.

In addition, it should be noted that the described SI scheme may be employed alone in the conventional parallel decoding apparatus and method, and thus, a storage device with smaller memory size may be used to obtain the approximated initial conditions. In this case, once the start point k of the sub-block boundary is obtained after dividing the sub-blocks (for example, the start point k of the effective data portion without overlapping, or the start point (k−L) of the overlapped portion with overlapping), the (k−L) in the above equation is replaced by k so as to obtain the approximated initial conditions.

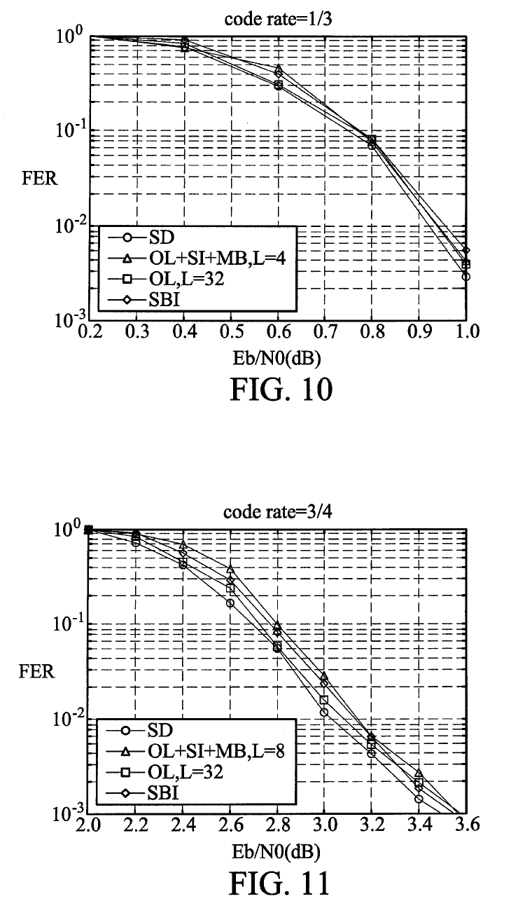

FIGS. 10-17 are diagrams of simulated results of the present invention. The simulation employs the Turbo codes defined in CMDA 2000 (Code Division Multiple Access 2000), and the decoder employs the max-log-map (Max Logarithmic Maximum A Posteriori) algorithm. The length of the interleaver N=2014, and the code rates are ⅓ and ¾. The maximum numbers of iterations Iₘₐₓ=8, the number of sub-blocks Q=21, and the offset Δ=7.

FIG. 10 shows the simulated Frame Error Rate (FER) under the OL+SI+MB scheme with code rate ⅓ (according to the third embodiment of the invention). For FER=0.0 1, with a very small overlap length L=4, the simulation result approaches the serial decoding (SD) scheme (with loss under 0.02 dB, where the unit length represents 0.1 dB in the x axis, similar to the other figures), which is almost the same as the result achieved by the conditional OL scheme with a much longer overlap length L=32, or the result achieved by the SBI scheme.

FIG. 11 shows the simulation result with code rate ¾. It can be seen that with a very small overlap length L=8, the FER difference when compared to SD scheme is only about 0.1 dB. It should be noted that the SI and MB schemes can be employed alone.

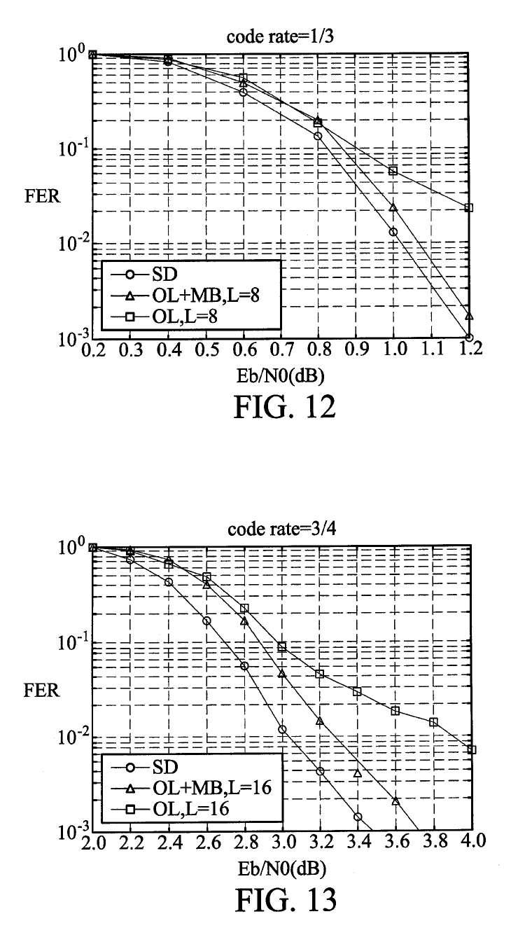

FIG. 12 shows the simulation results under the OL+MB (without SI) scheme with code rate ⅓ and overlap length L=8. Compared to the SD, the performance loss is about 0.05 dB at FER=0.01, while for the condition OL scheme with L=8 (i.e., with the same decoding speed and computation complexity as the OL+MB scheme), the performance is poor.

FIG. 13 shows the simulation result of an OL+MB scheme when L=16. It can be seen that the difference with respect to the SD scheme is only about 0.2 dB at FER=0.01 while for the condition OL scheme with the same overlap length, the loss exceeds 0.8 dB.

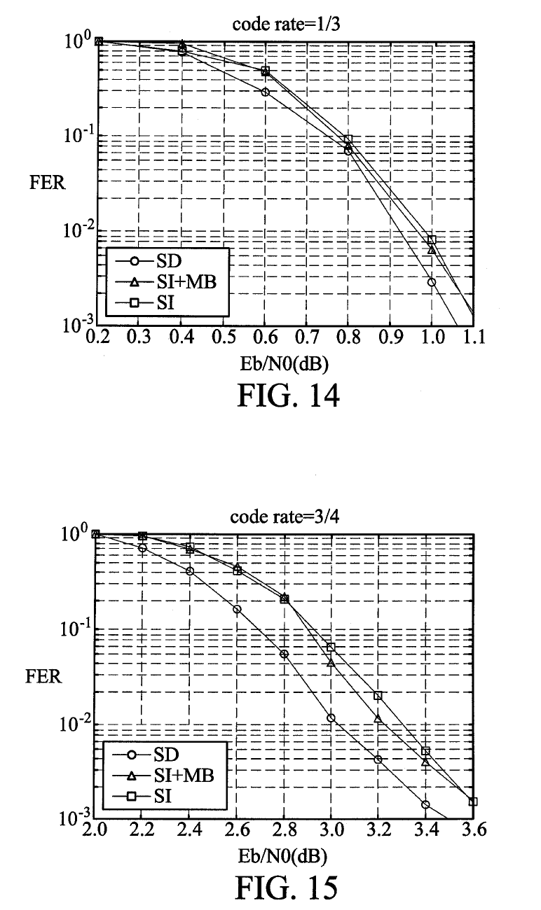

FIG. 14 shows the simulation results of SI only and SI+MB schemes with code rate ⅓. FIG. 15 shows the simulation results with code rate ¾. In these two schemes (SI only and SI+MB), the sub-blocks are not overlapped (L=0). For the ⅓ code rate, compared to the SD scheme, the loss of SI only and SI+MB schemes are both within 0.1 dB. For the ¾ code rate, the loss are respectively 0.3 dB and 0.2 dB. Under the low code rate condition, the performance of SI is almost the same as SI+MB. That is, the improvement brought by MB is small because the performance of SI is good enough. Thus, the space to be improved is very small. In this way, for a low code rate condition, design is possible with using only SI, and without employing the overlapping (OL) and moving boundary (MB) schemes. However, for a high code rate, MB or slight overlap is important.

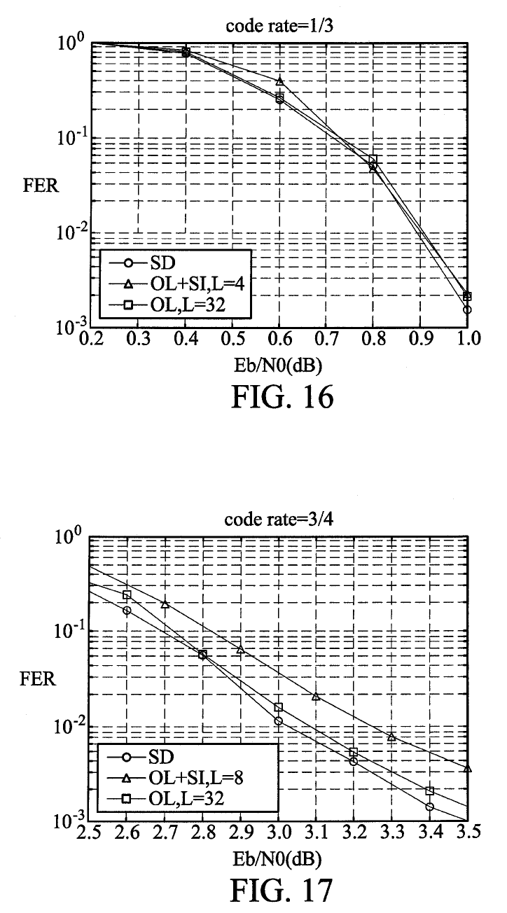

FIGS. 16 and 17 shows the OL+SI scheme having achieved good performance with slight overlap (L is small). To be more specific, for the ⅓ code rate, the OL+SI scheme with L=4 achieves as good a simulation result as the conventional OL with L=32; however, the former increases speed by about 20%.

The Bit Error Rate (BER) simulation results (not shown) are similar to the FER simulation results.

According to embodiments of the invention, two novel schemes are provided, the SI scheme storing the index of the most possible state and the MB scheme moving the sub-block boundary. With the aid of the SI and MB schemes, the overlap length can be greatly reduced so as to increase the decoding speed. One of ordinary skill in the art will readily appreciate that the schemes may be flexibly designed and combined, and may be integrated with the existing OL scheme so as to fulfill different requirements. The possible designs include MB, OL+MB, SI+MB, OL+SI+MB, SI or OL+SI . . . etc. All of the designs have different performances, decoding speeds and memory requirements.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A method for parallel decoding and data processing of Turbo codes, comprising:
a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and
a boundary moving step for moving at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size.

2. The parallel decoding and data processing method as claimed in claim 1, wherein the codeword dividing step further comprises:
an overlapping step for overlapping adjacent sub-blocks of the Q sub-blocks so that an effective data length M of the qth sub-block is kept unchanged, and overlap lengths of the qth sub-block with the (q−1)th sub-block and the (q+1)th sub-block are respectively equal to L, wherein L≧0, 2≦q≦Q−1, and q is a positive integer.

3. The parallel decoding and data processing method as claimed in claim 2, wherein a start point of a forward processing procedure of the qth sub-block during the pth decoding iteration relates to a product of M and q and a product of L and q, and a start point of a backward processing procedure of the qth sub-block during the pth decoding iteration relates to a product of q and a sum of M and L, and wherein when all of the boundaries are moved in the (p+n)th decoding iteration, the start point of the forward processing procedure of the qth sub-block by the offset Δ is moved during the (p+n)th decoding iteration, and the start point of the backward processing procedure of the qth sub-block by the offset Δ is moved during the (p+n)th decoding iteration.

4. The parallel decoding and data processing method as claimed in claim 3, wherein a start point of a forward or backward processing procedure of a q′th sub-block is k where 1≦q′≦Q, and q′ is an integer, further comprising:
a storing step for storing an index of a state (s*) of a maximum probability of the calculation results of the forward processing procedure or backward processing procedure of a p′th decoding iteration for the q′th sub-block during the p′th decoding iteration, wherein when an initial condition (s) is with the state of the maximum probability in the forward processing or backward processing procedure of a (p′+1)th decoding iteration for the q′th sub-block, a reliability of the initial condition (s) is 0, wherein p′ is a positive integer and 1≦p′<P.

5. The parallel decoding and data processing method as claimed in claim 4, wherein the storing step further comprises:
when the initial condition (s) is not compliant with the state of the maximum probability (s*), that is s≠s*, the initial condition relates to a difference between a reliability of the state (s*) of the maximum probability and a reliability of a state (s′) of a second highest probability.

6. A method for parallel decoding and data processing of Turbo codes, comprising:
a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and
a storing step for storing an index of a state (s*) of a maximum probability of the calculation results of a forward processing or a backward processing procedure of a pth decoding iteration for the qth sub-block during the pth decoding iteration, wherein when an initial condition (s) is with the state of the maximum probability in the forward processing or backward processing procedure of a (p+1)th decoding iteration for the qth sub-block, a reliability of the initial condition (s) is 0, wherein a start point of the forward or the backward processing procedure of the qth sub-block is k, where 1≦q≦Q, and q′ is an integer, and p is a positive integer and 1≦p<P.

7. A method for parallel decoding and data processing of Turbo codes, comprising:
a codeword dividing step for dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and
a storing step for storing an index of a state (s*) of a maximum probability of the calculation results of a forward processing or a backward processing procedure of a pth decoding iteration for the qth sub-block during the pth decoding iteration, wherein when an initial condition (s) in a forward processing or a backward processing procedure of a (p+1)th decoding iteration for the qth sub-block is not compliant with the state of the maximum probability (s*), that is s≠s*, the initial condition relates to a difference between a reliability of the state (s*) of the maximum probability and a reliability of a state (s′) of a second highest probability.

8. The parallel decoding and data processing method as claimed in claim 6 or 7, wherein the codeword dividing step further comprises:
an overlapping step for overlapping adjacent sub-blocks of the Q sub-blocks so that an effective data length M of the qth sub-block is kept unchanged, and overlap lengths of the qth sub-block with the (q−1)th sub-block and the (q+1)th sub-block are respectively equal to L, wherein L≧0, 2≦q≦Q−1, and q is a positive integer.

9. An apparatus for parallel decoding and data processing of Turbo codes, comprising:
a codeword dividing device dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and
a boundary moving device moving at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size.

10. The parallel decoding and data processing apparatus as claimed in claim 9, wherein the codeword dividing device further comprises:
an overlapping device overlapping adjacent sub-blocks of the Q sub-blocks so that an effective data length M of the qth sub-block is kept unchanged, and overlap lengths of the qth sub-block with the (q−1)th sub-block and the (q+1 )th sub-block are respectively equal to L, wherein L≧0, 2≦q≦Q−1, and q is a positive integer.

11. The parallel decoding and data processing apparatus as claimed in claim 10, wherein a start point of a forward processing procedure of the qth sub-block during the pth decoding iteration relates to a product of M and q and a product of L and q, and a start point of a backward processing procedure of the qth sub-block during the pth decoding iteration relates to a product of q and a sum of M and L, and wherein when all of the boundaries are moved in the (p+n)th decoding iteration, the start point of the forward processing procedure of the qth sub-block by the offset Δ is moved during the (p+n)th decoding iteration, and the start point of the backward processing procedure of the qth sub-block by the offset Δ is moved during the (p+n)th decoding iteration.

12. The parallel decoding and data processing apparatus as claimed in claim 11, wherein a start point of a forward or backward processing procedure of a q′th sub-block is k, where 1≦q′≦Q, and q′ is an integer, further comprising:
a storing device for storing an index of a state (s*) of a maximum probability of the calculation results of the forward processing or backward processing procedure of a p′th decoding iteration for the q′th sub-block during the p′th decoding iteration, wherein when an initial condition (s) is with the state of the maximum probability in the forward processing or backward processing procedure of a (p′+1)th decoding iteration for the q′th sub-block, a reliability of the initial condition (s) is 0, wherein p′ is a positive integer and 1≦p′<P.

13. The parallel decoding and data processing apparatus as claimed in claim 12, wherein the storing device further comprises:
when the initial condition (s) is not compliant with the state of the maximum probability (s*), that is s≠s*, the initial condition relates to a difference between a reliability of the state (s*) of the maximum probability and a reliability of a state (s′) of a second highest probability.

14. An apparatus for parallel decoding and data processing of Turbo codes, comprising:
a parallel decoding and data processing device for receiving input data, comprising:
a codeword dividing device dividing a whole codeword into Q sub-blocks to form a plurality of boundaries between adjacent sub-blocks of the Q sub-blocks so as to decode the Q sub-blocks, wherein the decoding process comprises P times of decoding iterations, and wherein Q is a positive integer and Q>1 and P is a positive integer and P>1; and
a boundary moving device moving at least one position of the boundaries formed in a pth decoding iteration by an offset Δ before performing a (p+n)th decoding iteration, wherein p is a positive integer and 1≦p<P, n is a positive integer and 1≦n<P−p, and the offset Δ is set as a fixed step size;
a Turbo code decoding device coupled to the parallel decoding and data processing device and receiving decoded data of the sub-blocks, wherein the Turbo code decoding device comprises a plurality of interleavers and a plurality of de-interleavers to Turbo decode the decoded data of the sub-blocks generated by the parallel decoding and data processing device; and
a storing device coupled to the parallel decoding and data processing device and the Turbo code decoding device for storing the input data and decoded results.
